(19) United States
(12) Patent Application Publication
(10) Pub. No.: US 2008/0272434 A1
(43) Pub. Date: Nov. 6, 2008

(54) NON-VOLATILE MEMORY DEVICE AND METHOD OF MANUFACTURING THE SAME

(75) Inventors: Jun-Beom PARK, Seoul (KR); Ki-Nam KIM, Seoul (KR); Soon-Moon JUNG, Gyeonggi-do (KR); Jae-Hoon JANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/876,638

(22) Filed: Oct. 22, 2007

(30) Foreign Application Priority Data
Oct. 20, 2006 (KR) 2006-102310

(51) Int. Cl. H01L 27/115; H01L 21/8247

(52) U.S. Cl. 257/347; 438/166; 257/E27.103; 257/E21.68

(57) ABSTRACT

A non-volatile memory device and a method of manufacturing the same are disclosed. In the non-volatile memory device, first gate structures and first impurity diffusion regions are formed on a substrate. A first insulating interlayer is formed on the substrate. A semiconductor layer including second gate structures and second impurity diffusion regions is formed on the first insulating interlayer. A second insulating interlayer is formed on the semiconductor layer. A contact plug connecting the first impurity diffusion regions to the second impurity diffusion regions is formed. A common source line connected to the contact plug is formed on the second insulating interlayer. The common source line connected to the first and second impurity diffusion regions is formed over a top semiconductor layer.

### CROSS-REFERENCE TO RELATED APPLICATION

This application claims the benefit of foreign priority under 35 USC § 119 to Korean Patent Application No. 2006-102310 filed on Oct. 20, 2006, the contents of which are incorporated herein by reference in their entirety.

### BACKGROUND

1. Field of the Invention

Embodiments exemplarily described herein relate generally to non-volatile memory devices and methods of manufacturing non-volatile memory devices. More particularly, embodiments exemplarily described herein relate to a NOR-type non-volatile memory device having gate structures that are vertically stacked and a method of manufacturing the NOR-type non-volatile memory device.

2. Description of the Related Art

Semiconductor memory devices are generally classified as non-volatile memory devices or volatile memory devices. Volatile memory devices such as dynamic random access memory (DRAM) and static random access memory (SRAM) lose data over time and have a high operation speed. On the other hand, non-volatile memory devices such as read only memory (ROM) hold stored data permanently, but have a low operation speed. A non-volatile memory device, which is represented by a flash memory device such as an electrically erasable and programmable ROM (EEPROM), has been widely used over the years. Flash memory devices electrically write and read data by using Fowler-Nordheim (F-N) tunneling or channel hot electron injection.

Flash memory devices are generally classified as NAND-type and NOR-type, in accordance with their circuit structure. In NAND-type flash memory devices, a number of cell transistors are connected in series to form a unit string. The unit strings are connected in parallel between a bit line and a ground line.

In contrast, NOR-type flash memory devices have a parallel circuit structure in which the respective cell transistors are coupled in parallel between the bit line and the ground line. Therefore, NOR-type flash memory devices may have a high operation speed for reading and erasing data by a block unit. However, the NOR-type flash memory device may have a relatively low degree of integration. As a result, NOR-type flash memory devices may have a relatively small data storage capacity. Thus, semiconductor manufacturing processes capable of forming vertically arranged NOR-type cell transistors have been developed to increase the data storage capacity of NOR-type flash memory devices.

FIG. 1 is a cross-sectional view illustrating a conventional NOR-type non-volatile memory device.

Referring to FIG. 1, lower gate structures 110 and lower impurity diffusion regions 111 and 112 are formed on a semiconductor substrate 100. The lower gate structures 110 include a tunnel oxide layer 102, a floating gate 104, a dielectric layer 106 and a control gate 108. The lower impurity diffusion regions 111 and 112 include lower source regions 111 electrically connected to lower common source lines 118 and lower drain regions 112 electrically connected to bit lines 138.

A first insulating interlayer 114 is formed on the semiconductor substrate 100. First contact plugs 116 are formed through the first insulating interlayer 114 to make contact with the lower source regions 111. Lower common source lines 118 are formed on the first contact plugs 116.

A second insulating interlayer 120 is formed on the lower common source lines 118. A semiconductor layer 122 is formed on the second insulating interlayer 120. Upper gate structures 124 and upper impurity diffusion regions 125 and 126 are formed on the semiconductor layer 122, and a third insulating interlayer 128 is formed on the upper gate structures 124 and the second insulating interlayer 120. Second contact plugs 130 are formed through the second insulating interlayer 128. The second contact plugs 130 are electrically connected to upper source regions 125 of the upper impurity diffusion regions 125 and 126 and upper common source lines 132.

One or more additional semiconductor layers 122 may be formed over the semiconductor substrate 100. If one or more additional semiconductor layers 122 are formed over the semiconductor substrate 100, additional gate structures, impurity diffusion regions and common source lines are formed on each of the additional semiconductor layers 122. However, an additional insulating interlayer must be provided between an underlying common source line and the additional semiconductor layer 112. As a result, processes for the NOR-type non-volatile memory device may become complex and the time and cost associated with for manufacturing the NOR-type non-volatile memory device may undesirably increase.

Further, a second contact plug 130 is formed for every two gate structures that are formed on the semiconductor layer 122 and third contact plugs 136 are formed to be connected to bit lines 138. Based on this structure, the cell area of the NOR-type non-volatile memory device may be undesirably increased.

The bit lines 138 are formed on a fourth insulating interlayer 134 formed over a topmost semiconductor layer 122. The bit lines 138 are electrically connected to drain regions 112 and 126 formed on each of the semiconductor layers 122 and the semiconductor substrate 100 through the third contact plugs 136. An opening (not shown) for forming the third contact plugs 136 may have a relatively high aspect ratio. Particularly, the first and second common source lines 118 and 132 are formed over the semiconductor substrate 100 and each of the semiconductor layers 122. As a result, insulating interlayers must be interposed between the common source lines 118 and 132 and the semiconductor layers 122. Thus, an overall thickness of the insulating interlayers may increase which, in turn, leads to a significant increase in the aspect ratio of the openings used in forming the third contact plugs 136. As a result, processes for forming the openings for forming the third contact plugs 136 and reliably filling the openings may become difficult.

### SUMMARY OF THE INVENTION

Exemplary embodiments disclosed herein may be adapted to provide a memory device including simple common source lines. Exemplary embodiments disclosed herein may be adapted to provide a method of manufacturing a memory device by simple processes.

One embodiment exemplarily described herein can be characterized as a memory device that includes a semiconductor substrate including first gate structures and first impurity diffusion regions; a first insulating interlayer formed on the semiconductor substrate; a semiconductor layer formed on the first insulating interlayer, the semiconductor layer including second gate structures and second impurity diffusion regions; a second insulating interlayer formed on the semiconductor layer; a contact plug electrically connecting one of the first impurity diffusion regions to one of the second impurity diffusion regions; and a common source line formed on the second insulating interlayer, the common source line being electrically connected to the contact plug.

One embodiment exemplarily described herein can be characterized as a method of manufacturing a memory device that includes forming first gate structures and first impurity diffusion regions on a semiconductor substrate; forming a first insulating interlayer on the semiconductor substrate; forming a semiconductor layer on the first insulating interlayer, the semiconductor layer including second gate structures and second impurity diffusion regions; forming a second insulating interlayer on the semiconductor layer; forming a contact plug electrically connecting one of the first impurity diffusion regions to one of the second impurity diffusion regions; and forming a common source line on the second insulating interlayer, the common source line being electrically connected to the contact plug.

### BRIEF DESCRIPTION OF THE DRAWINGS

The above and other features of the embodiments exemplarily described above will become readily apparent by reference to the following detailed description when considered in conjunction with the accompanying drawings wherein:

FIG. 1 is a cross-sectional view illustrating a conventional NOR-type non-volatile memory device;

FIG. 2 is a plan view illustrating a NOR-type non-volatile memory device in accordance with an exemplary embodiment;

FIG. 3 is a cross-sectional view taken along line II-II′ shown in FIG. 2;

FIG. 4 is a cross-sectional view taken along line I-I′ shown in FIG. 2;

FIGS. 5 to 13 are cross-sectional views illustrating an exemplary method of manufacturing a NOR-type non-volatile memory device in accordance with exemplary embodiments of the present invention;

FIG. 14 is a cross-sectional view illustrating a NOR-type non-volatile memory device in accordance with another exemplary embodiment;

FIG. 15 is a cross-sectional view taken along line IV-IV′ shown in FIG. 14;

FIG. 16 is a cross-sectional view taken along line III-III′ shown in FIG. 14;

FIGS. 17 and 18 are cross-sectional views illustrating an exemplary method of manufacturing the NOR-type non-volatile memory device in accordance with exemplary embodiments of the present invention;

FIGS. 19 to 21 are cross-sectional views illustrating an exemplary process forming a semiconductor layer using a bonding process;

FIGS. 22 to 24 are cross-sectional views illustrating an exemplary process for forming a semiconductor layer using a selective epitaxial growth process;

FIG. 25 is a cross-sectional view illustrating a mechanism of erasing a data from a NOR-type non-volatile memory device including a semiconductor layer having the substantially the same thickness as that of an impurity diffusion region formed in the semiconductor layer; and

FIG. 26 is a cross-sectional view illustrating a mechanism of erasing a data from a NOR-type non-volatile memory device including a semiconductor layer having a thickness greater than that of an impurity diffusion region formed in the semiconductor layer.

### DETAILED DESCRIPTION

Exemplary embodiments of the present invention will now be described more fully hereinafter with reference to the accompanying drawings. These embodiments may, however, be realized in many different forms and should not be construed as limited to the example embodiments set forth herein. Rather, these exemplary embodiments are provided so that this disclosure will be thorough and complete, and will fully convey the scope of the present invention to those skilled in the art. In the drawings, the sizes and relative sizes of layers, patterns and regions may be exaggerated for clarity.

It will be understood that when an element or a layer is referred to as being “on,” “connected to” or “coupled to” another element or another layer, it can be directly on, connected or coupled to the other element, the other layer or intervening elements or layers may be present. In contrast, when an element is referred to as being “directly on,” “directly connected to” or “directly coupled to” another element or another layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, patterns, layers and/or sections, these elements, components, regions, patterns, layers and/or sections should not be limited by these terms. These terms are only used to distinguish one element, component, region, pattern, layer or section from another region, layer or section. Thus, a first element, component, region, pattern, layer or section discussed below could be termed a second element, component, region, pattern, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention as defined in the claims. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components and/or groups thereof.

Exemplary embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention as defined in the claims.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a NOR-type non-volatile memory device and a method of manufacturing the NOR-type non-volatile memory device will now be described.

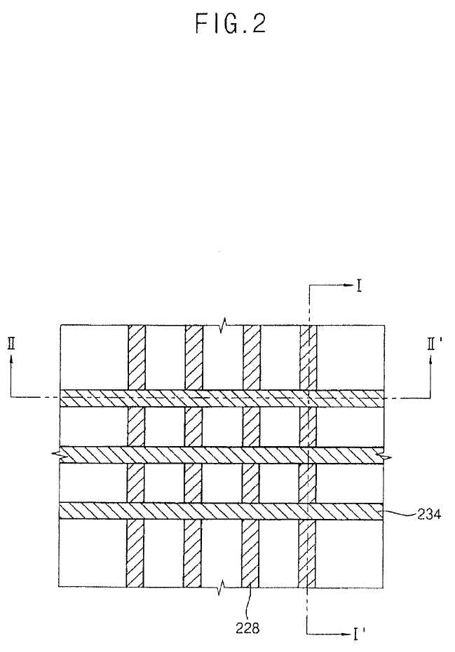

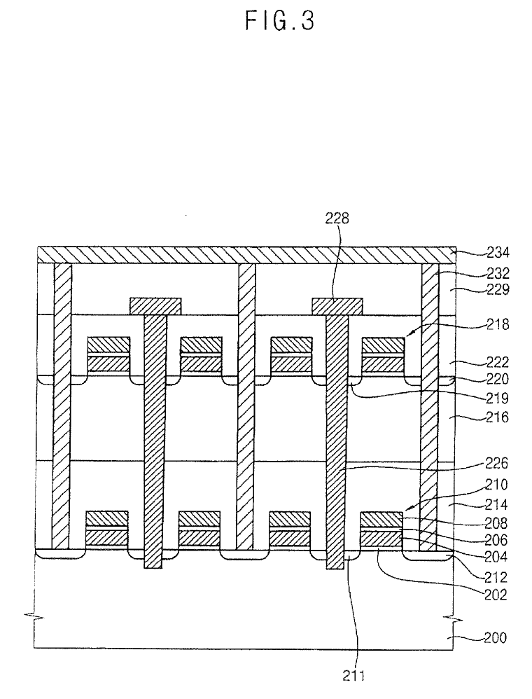

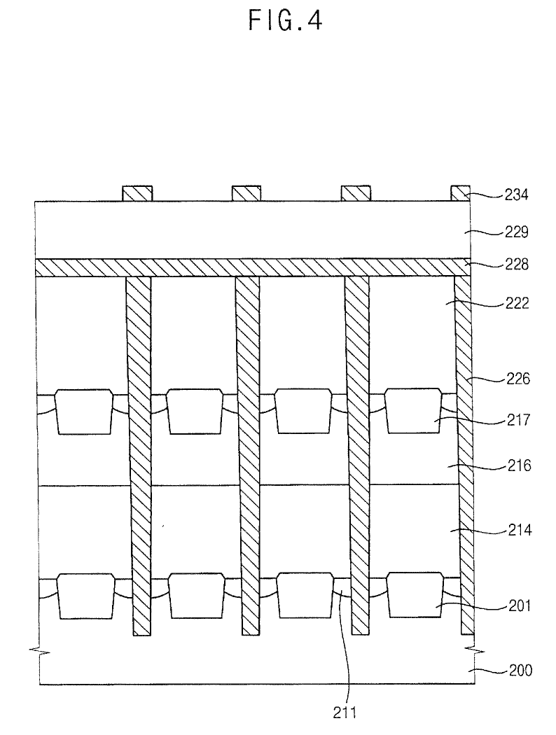

FIG. 2 is a plan view illustrating a NOR-type non-volatile memory device in accordance with an exemplary embodiment. FIG. 3 is a cross-sectional view taken along line II-II′ shown in FIG. 2. FIG. 4 is a cross-sectional view taken along line I-I′ shown in FIG. 2.

Referring to FIGS. 2 to 4, a NOR-type non-volatile memory device may, for example, include a semiconductor substrate 200, a semiconductor layer 216, a plurality of gate structures 210 and 218, a plurality of impurity diffusion regions 211, 212, 219 and 220, a plurality of insulating interlayers 214, 222 and 229, a plurality of common source lines 228 and a plurality of bit lines 234. The gate structures 218 and the impurity diffusion regions 219 and 220 are formed on the semiconductor layer 216. The insulating interlayers 222 and 229 are formed on the semiconductor layer 216. The common source lines 228 are formed in the insulating layer 229. The bit lines 234 are formed on the insulating layer 229.

In the illustrated embodiment, the NOR-type non-volatile memory device includes only one semiconductor layer 216. In another embodiment, however, that the one or more additional semiconductor layers 216 may be formed over the semiconductor substrate 100. In such an embodiment, additional gate structures, impurity diffusion regions and an insulating interlayer may be formed on each of the additional semiconductor layers 216. In such an embodiment, the common source lines 228 are formed over a topmost one of the additional insulating interlayers. Accordingly, the third insulating interlayer 229 is formed over the common source lines 228 and the topmost one of the additional insulating interlayers and the bit lines 234 are formed over the third insulating interlayer 229.

The semiconductor substrate 200 may, for example, include a silicon wafer (e.g., a single crystalline silicon wafer), or the like. As illustrated in FIG. 4, first isolation layer patterns 201 are formed at surfaces of the semiconductor substrate 200.

A plurality of lower gate structures 210 (also referred to herein as “first gate structures”) are formed on the semiconductor substrate 200. The lower gate structures 210 may be spaced apart from one another by a predetermined distance. The lower gate structures 210 may extend along a first direction.

In one embodiment, each lower gate structure 210 may, for example, include a tunnel oxide layer pattern 202, a floating gate electrode 204, a dielectric layer pattern 206 and a control gate electrode 208. The floating gate electrode 204 is formed under the dielectric layer pattern 206. The floating gate electrode 204 may have an isolated hexahedral structure. The floating gate electrode 204 and the control gate electrode 208 may extend along the first direction. The lower gate structures 210 may further include first spacers (not shown) formed on sidewalls thereof.

In another embodiment, each lower gate structure 210 may include a tunnel oxide layer, a charge trapping layer, a blocking insulating layer and a gate conductive layer.

Lower impurity diffusion regions 211 and 212 are formed at surface portions of the semiconductor substrate 200 exposed between adjacent lower gate structures 210. The lower impurity diffusion regions 211 and 212 include lower source regions 211 (also referred to herein as “first impurity diffusion regions”) electrically connected to the common source lines 228 and lower drain regions 212 (also referred to herein as “third impurity diffusion regions”) electrically connected to the bit lines 234.

The lower impurity diffusion regions 211 and 212 are electrically isolated from one another by the first isolation layer pattern 201. The lower source regions 211 and the lower drain regions 212 are alternately formed at opposing sides of each of the lower gate structures 210.

A first insulating interlayer 214 is formed on the semiconductor substrate 200 on which the lower gate structures 210 and the lower impurity diffusion regions 211 and 212 are formed. The first insulating interlayer 214 may include, for example, an oxide (e.g., silicon oxide), or the like.

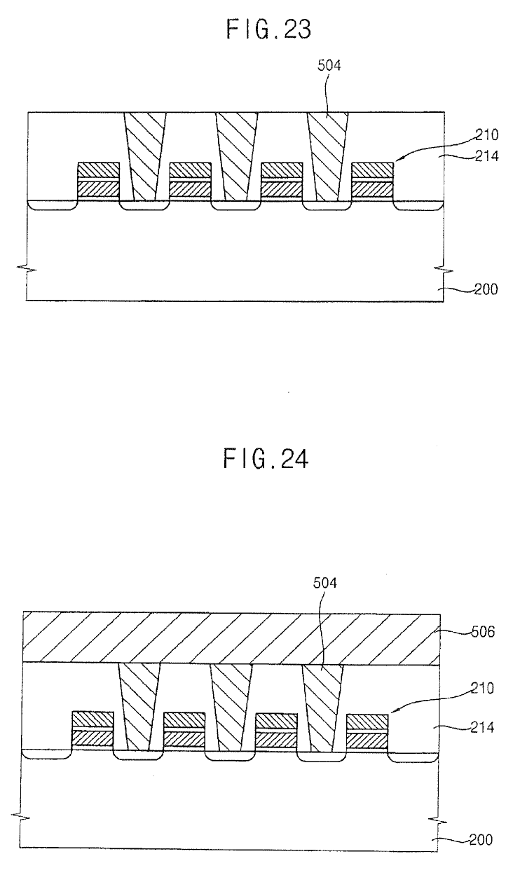

In one embodiment, connecting members (not shown) may be formed through the first insulating interlayer 214. Each of the connecting members may have a column-type shape. The connecting member may connect the semiconductor layer 216 to the semiconductor substrate 200. The connecting members may be formed using a selective epitaxial growth process. The connecting member and the semiconductor substrate 200 may include substantially the same material. An exemplary process for forming the connecting members is described in greater detail with respect to FIGS. 22 and 23.

The semiconductor layer 216 is formed on the first insulating interlayer 214. Second isolation layer patterns 217 and upper impurity diffusion regions 219 and 220 are formed at surface portions of the semiconductor layer 216. Upper gate structures 218 (also referred to herein as “second gate structures”) are formed on the semiconductor layer 216. The upper gate structures 218 and the upper impurity diffusion regions 219 and 220 may be substantially identical to the lower gate structures 210 and the lower impurity diffusion regions 211 and 212, respectively. Accordingly, the upper impurity diffusion region 219 may be referred to as an upper source region 219 (or a “second impurity diffusion region”) and the upper impurity diffusion region 220 may be referred to as an upper drain region 220 (or a “fourth impurity diffusion region”). Accordingly, any further explanation of the processes for forming the upper gate structures 218 and the upper impurity diffusion regions 219 and 220 will be omitted to avoid for the sake of brevity.

In one embodiment, a location of the upper gate structures 218 relative to the semiconductor substrate 200 may substantially correspond to a location of the lower gate structures 210 relative to the semiconductor substrate 200. In another embodiment, a location of the upper impurity diffusion regions 219 and 220 relative to the semiconductor substrate 200 may substantially correspond to a location of the lower impurity diffusion regions 211 and 212 relative to the semiconductor substrate 200. Further, the upper gate structures 218 may extend along a direction parallel (or substantially parallel) with the lower gate structures 210.

A second insulating interlayer 222 is formed on the semiconductor layer 216. The common source lines 228 are disposed on the second insulation interlayer 222. The common source lines 228 extend along a direction parallel (or substantially parallel) with the lower and the upper gate structures 210 and 218. In one embodiment, a location of the common source lines 228 relative to the semiconductor substrate 200 may substantially correspond to a location of the lower and the upper source regions 211 and 219 relative to the semiconductor substrate 200.

First contact plugs 226 electrically connect the common source lines 228 to the lower and the upper source regions 211 and 219. For example, the first contact plugs 226 are formed through the second insulating interlayer 222, the semiconductor layer 216 and the first insulating interlayer 214. The first contact plugs 226 may extend into the semiconductor substrate 200.

Each of the first contact plugs 226 includes a lower portion contacting the lower source region 211 and a side portion contacting the upper source region 219. Thus, the first contact plugs 226 electrically connect the common source lines 228 to the lower and the upper source regions 211 and 219.

A third insulating interlayer 229 is formed on the second insulating interlayer 222 on which the first contact plugs 226 are formed. In one embodiment, the third insulating interlayer 229 and the second insulating interlayer 222 may include substantially the same material. In another embodiment, the third insulating interlayer 229 and the second insulating interlayer 222 may include different materials.

The bit lines 234 are formed on the third insulating interlayer 229. The bit lines 234 are spaced apart from one another. The bit lines 234 vertically extend with respect to the common source lines 228. The bit lines 234 may, for example, include doped polysilicon.

The bit lines 234 are connected to second contact plugs 232. Accordingly, the second contact plugs 232 electrically connect the bit lines 234 to the lower drain regions 212 and the upper drain regions 220. For example, the second contact plugs 232 may be formed through the third insulating interlayer 229, the second insulating interlayer 222, the semiconductor layer 216 and the first insulating interlayer 214. The second contact plugs 232 include a lower portion contacting the lower drain regions 212 and a side portion contacting upper drain regions 220, respectively. Thus, the bit lines 234 contacting the second contact plugs 232 are electrically connected to the lower drain regions 212 and the upper drain regions 220.

The NOR-type non-volatile memory device may further include spacers (not shown) formed on sidewalls of the second contact plugs 232. The spacers may, for example, include a nitride material, or the like. Further, the second contact plugs 232 may, for example, include doped polysilicon having impurities substantially the same as those included in the first impurity regions 211 and 212 and the second impurity regions 219 and 220.

Hereinafter, an exemplary method of manufacturing the NOR-type non-volatile memory device in FIGS. 2 to 4 will now be described.

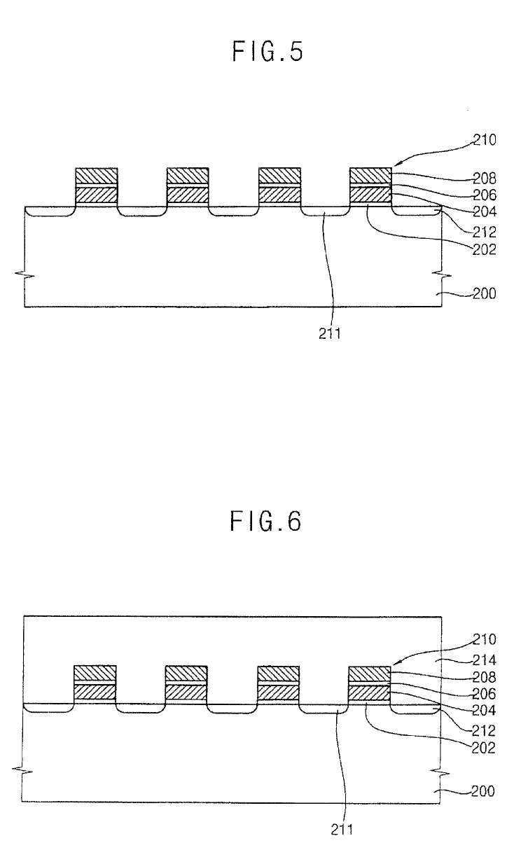

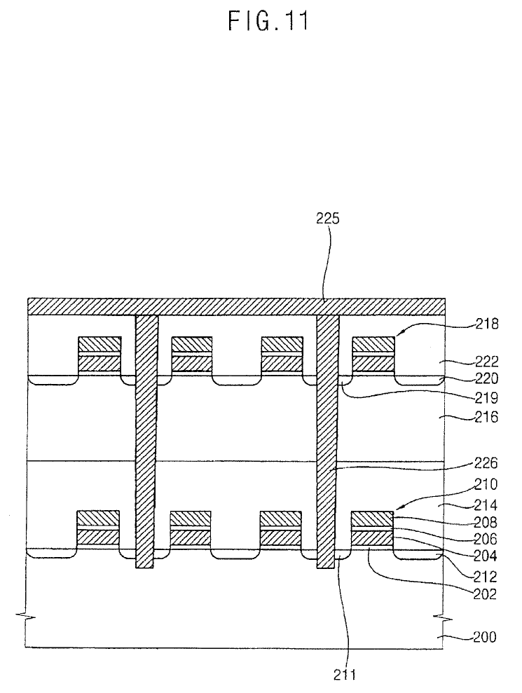

FIGS. 5 to 13 are cross-sectional views illustrating an exemplary method of manufacturing the NOR-type non-volatile memory device in accordance with exemplary embodiments of the present invention.

Referring to FIG. 5, first isolation layer patterns 201 are formed at surface portions of a semiconductor substrate 200 (e.g., a silicon wafer, or the like). The first isolation layer patterns 201 may be formed using an isolation process such as a shallow trench isolation (STI) process, or the like. Thus, first active regions are defined within the semiconductor substrate 200 by the first isolation layer patterns 201.

To form the first isolation layer patterns 201, a pad oxide layer (not shown) and a first mask pattern (not shown) may be formed on the semiconductor substrate 200. Portions of the pad oxide layer and the semiconductor substrate 200 exposed by the first mask pattern may be etched to form a pad oxide layer pattern (not shown) on the semiconductor substrate 200 and trenches at the surface portions of the semiconductor substrate 200. An isolation layer (not shown) may then be formed to fill the trenches. The isolation layer may then be partially removed until an upper face of the first mask pattern is exposed to form the isolation layer patterns 201 at the surface portion of the semiconductor substrate 200. The first mask pattern and the pad oxide layer pattern may be removed from the semiconductor substrate 200 after the first isolation layer patterns 201 are formed.

After forming the first isolation layer patterns 201, a tunnel insulating layer (not shown) and a first conductive layer (not shown), that is to be transformed into a floating gate electrode, are formed on the semiconductor substrate 200. The tunnel insulating layer may, for example, include silicon oxide. When the tunnel insulating layer includes silicon oxide, the tunnel insulating layer may be formed using a thermal oxidation process, a chemical vapor deposition (CVD) process, or the like. The first conductive layer may, for example, include polysilicon. The first conductive layer may, for example, be formed using a CVD process.

A second mask pattern (not shown) is then formed on the first conductive layer and the first conductive layer is partially etched using the second mask pattern as an etching mask to form first conductive layer patterns (not shown) on the tunnel insulating layer. The first conductive layer patterns extend along the first direction. The first conductive layer patterns are spaced apart from one another.

After forming the first conductive layer patterns, a dielectric layer (not shown) and a second conductive layer (not shown), that is to be transformed into a control gate, are formed. In one embodiment, the dielectric layer may, for example, be a multi-layered structure having an oxide layer, a nitride layer and an oxide layer that are sequentially formed on the first conductive layer patterns. In one embodiment, the dielectric layer may include a material having a relatively high dielectric constant. The dielectric layer may be formed using an atomic layer deposition (ALD) process, a CVD process, or the like. In one embodiment, the second conductive layer may have a double-layered structure including a doped polysilicon layer and a metal silicide layer.

Next, a third mask pattern (not shown) is formed on the second conductive layer and the second conductive layer, the dielectric layer, the first conductive layer pattern and the tunnel insulating layer are partially etched using the third mask pattern as an etching mask to form a control gate electrode 208, a dielectric layer pattern 206, a floating gate electrode 204 and a tunnel insulating layer pattern 202 on the semiconductor substrate 200. Thus, a plurality of lower gate structures 210, each including the control gate electrode 208, the dielectric layer pattern 206, the floating gate electrode 204 and the tunnel insulating layer pattern 202, may be formed on the semiconductor substrate 200.

In one embodiment, the control gate electrode 208 and the dielectric layer pattern 206 are formed to extend along a second direction perpendicular (or substantially perpendicular) to the first direction. Further, the floating gate electrode 204 is formed under the dielectric layer pattern 206. The floating gate electrode 204 may have an island shape and be isolated from neighboring floating gate electrodes. The floating electrode 204 may have a hexahedral shape.

As a result, lower gate structures 210 extending along the second direction are formed on the semiconductor substrate 200.

Although not illustrated, first spacers may be formed on sidewalls of the lower gate structures 210. The first spacers may, for example, be formed by forming a nitride layer (not shown) on the semiconductor substrate and over a surface of the lower gate structures 210 followed by anisotropically etching the nitride layer.

In one embodiment, a tunnel oxide layer (not shown), a charge trapping layer (not shown), a blocking insulating layer (not shown) and a gate conductive layer (not shown) may be sequentially formed on the semiconductor substrate 200. The tunnel oxide layer, the charge trapping layer, the blocking insulating layer and the gate conductive layer may then be patterned using a mask pattern to form the lower gate structures 210 on the semiconductor substrate 200.

Impurities are implanted into the semiconductor substrate 200 using the lower gate structures 210 as an ion implantation mask to form lower impurity diffusion regions 211 and 212 at surface portions of the semiconductor substrate 200 which are exposed between adjacent lower gate structures 210.

The lower impurity diffusion regions 211 and 212 are isolated from each other by the first isolation layer patterns 201. Further, the lower impurity diffusion regions 211 and 212 may serve as lower source regions 211 and lower drain regions 212, respectively. In one embodiment, the lower source regions 211 are electrically connected to subsequently-formed common source lines 228. The lower drain regions 212 are electrically connected to subsequently-formed bit lines 234.

Referring to FIG. 6, a first insulating interlayer 214 is formed on the semiconductor substrate 200 to cover the lower gate structures 210. The first insulating interlayer 214 may, for example, include an oxide capable of efficiently filling up gap between adjacent lower gate structures 210. For example, the oxide may include undoped silicate glass (USG), an O3-tetraehtylorthosilicate undoped silicate glass (O3-TEOS USG), a high density plasma (HDP) oxide, or the like or a combination thereof.

In one embodiment, the first insulating interlayer 214 may be densified by thermally treating the first insulating interlayer 214 at a temperature of about 800° C. to about 1,050° C. in an inert gas. The densified first insulating interlayer 214 may have a relatively low wet-etch rate in a subsequent cleaning process.

The first insulating interlayer 214 may be planarized by a planarization process such as an etch-back process, a chemical mechanical polishing (CMP) process, or the like, either alone or in a combination thereof.

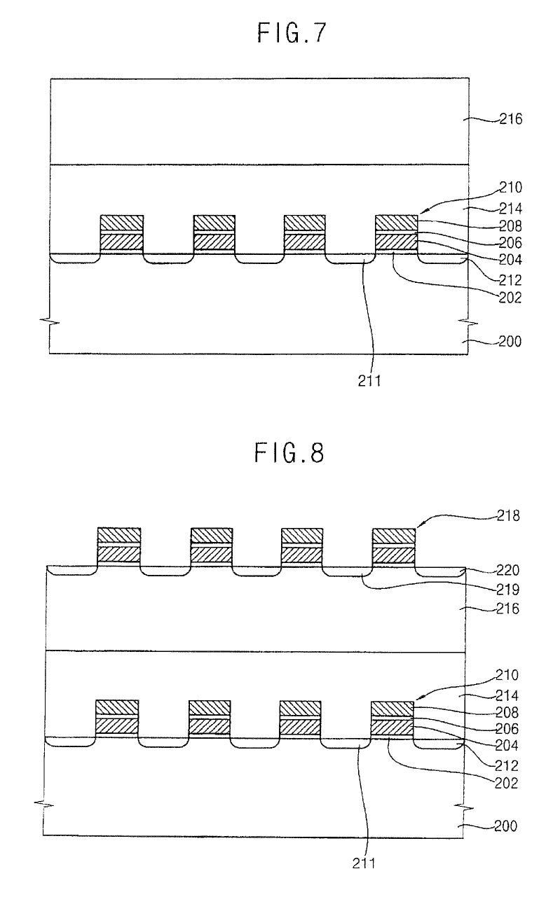

Referring to FIG. 7, a semiconductor layer 216 is formed on the first insulating interlayer 214.

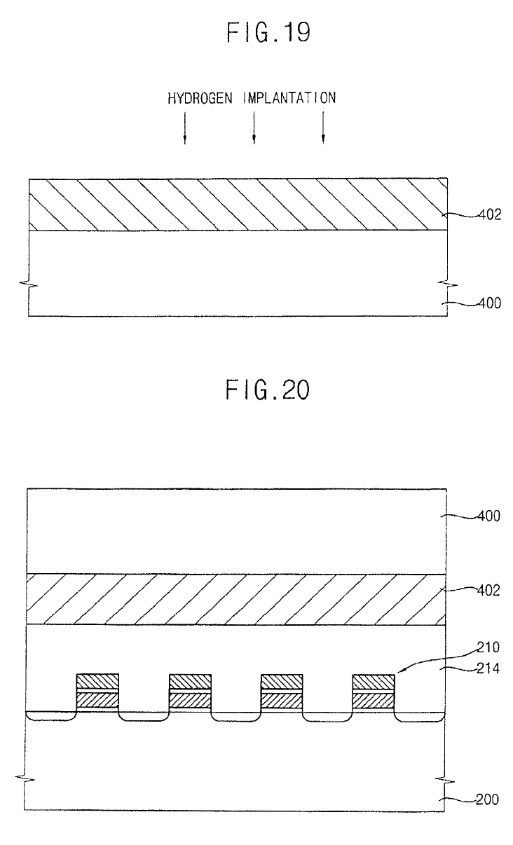

The semiconductor layer 216 may, for example, include single crystalline silicon. Variations of a thickness of the semiconductor layer 216 are possible. The semiconductor layer 216 may be formed using a bonding process or a selective epitaxial growth process. Exemplary processes for forming the semiconductor layer 216 will be described in greater detail below with respect to FIGS. 19 to 24.

Referring to FIG. 8, second isolation layer patterns 217 are formed at surface portions of the semiconductor layer 216 to define second active regions. Upper gate structures 218 are formed on the semiconductor layer 216. Upper impurity diffusion regions 219 and 220 are formed at surface portions of the semiconductor layer 216.

In one embodiment, the upper gate structures 218 are formed such that a location of the upper gate structures 218 relative to the semiconductor substrate 200 substantially corresponds to a location of the lower gate structures 210 relative to the semiconductor substrate 200. In one embodiment, the upper impurity diffusion regions 219 and 220 are disposed such that a location of the upper impurity diffusion regions 219 and 220 relative to the semiconductor substrate 200 substantially corresponds to a location of the lower impurity diffusion regions 211 and 212 relative to the semiconductor substrate 200. The upper gate structures 218 and the upper impurity diffusion regions 219 and 220 may be formed using substantially the same processes as those employed for forming the lower gate structures 210 and the lower impurity diffusion regions 211 and 212 described with reference to FIG. 5. Thus, any further explanation of the processes for forming the upper gate structures 218 and the upper impurity diffusion regions 219 and 220 will be omitted to avoid a redundancy.

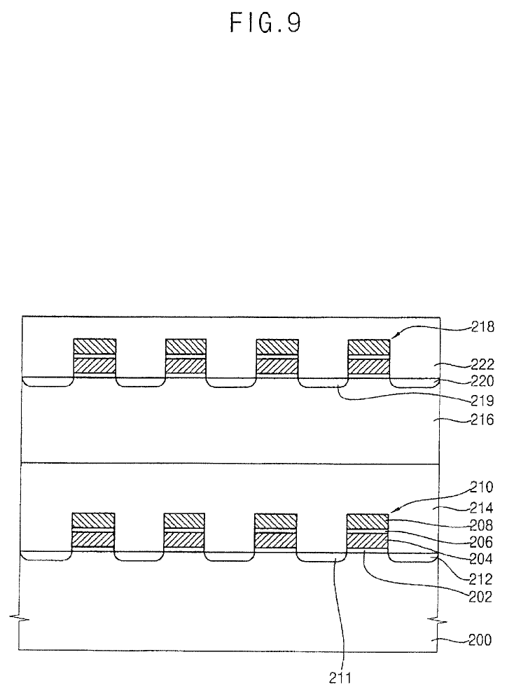

Referring to FIG. 9, a second insulating interlayer 222 is formed on the semiconductor layer 216 to cover the upper gate structures 218. The second insulating interlayer 222 may, for example, include an oxide. The second insulating interlayer 222 may be formed using substantially the same process as those for forming the first insulating interlayer 214 described with reference to FIG. 6. Thus, any further explanation of the process for forming the second insulating interlayer 222 will be omitted.

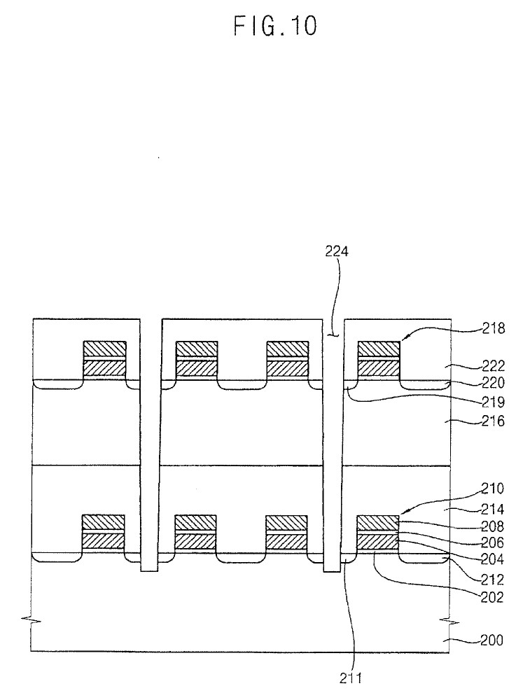

Referring to FIG. 10, first openings 224 may be formed through the second insulating interlayer 222, the semiconductor layer 216 and the first insulating interlayer 214. In one embodiment, the first openings 224 may be formed by forming a fourth mask pattern (not shown) on the second insulating interlayer 222 and partially etching the second insulating interlayer 222, the semiconductor layer 216 and the first insulating interlayer 214 using the fourth mask pattern as an etching mask.

The lower source regions 211 are partially exposed at a bottom region of the first opening 224. Further, the upper source regions 219 are exposed at a side region of the first openings 224.

In one embodiment, upper portions of the lower source regions 211 are exposed through the first openings 224. In another embodiment, a surface of the semiconductor substrate 200 is further etched to expose cross sections of the lower source regions 211 through the first openings 224.

After forming the first openings 224, the fourth mask pattern may be removed from the second insulating interlayer 222.

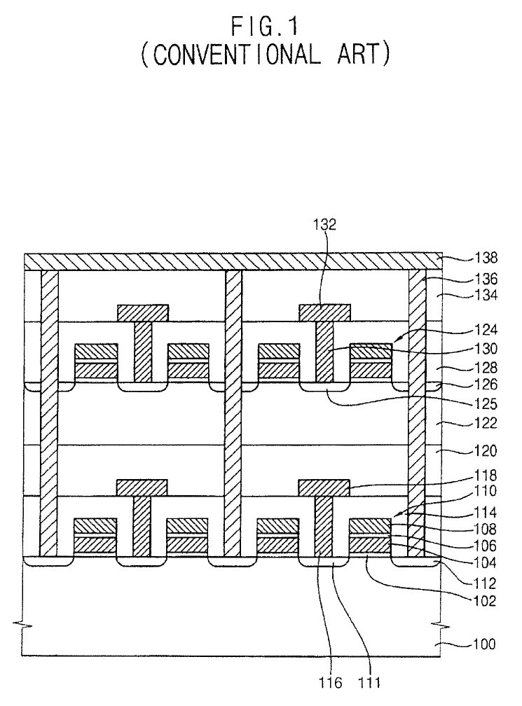

Referring to FIG. 1, a third conductive layer 225 is formed on the second insulating interlayer 222 to substantially fill the first openings 224. The third conductive layer 225 may, for example, include a metal, a metal silicide, or the like or a combination thereof. In one embodiment, the third conductive layer 225 may include tungsten or tungsten silicide.

Portions of the third conductive layer 225 filling the first openings 224 are first contact plugs 226. The first contact plugs 226 contact the lower source regions 211 and the upper source regions 219. For example, lower portions of the first contact plugs 226 contact the lower source regions 211 and side portions of the first contact plugs 226 contact the upper source regions 219. Thus, the lower source regions 211 and the upper source regions 219 are electrically connected to one another.

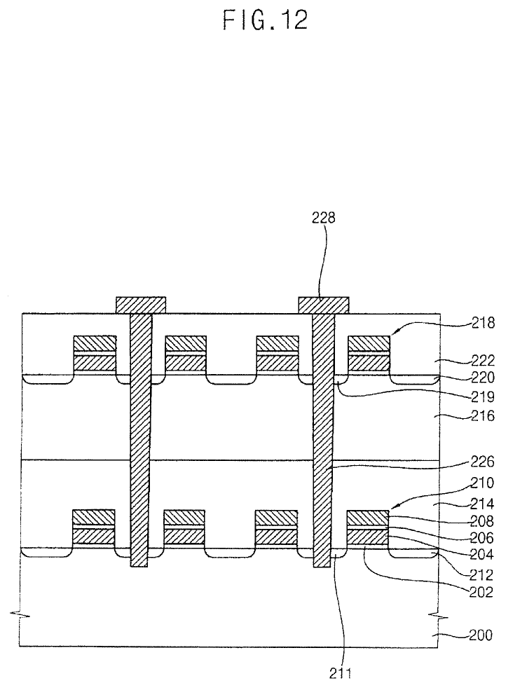

Referring to FIG. 12, common source lines 228 are formed on the second insulating interlayer 222. In one embodiment, the common source lines 228 may be formed by forming a fifth mask pattern (not shown) on the third conductive layer 225 and partially etching the third conductive layer 225 using the fifth mask pattern as an etching mask.

The common source lines 228 extend along a direction that is parallel (or substantially parallel) with the lower and the upper gate structures 210 and 218. The common source lines 228 contact the first contact plugs 226. Thus, the lower source regions 211 and the upper source regions 219 are electrically connected to the common source lines 228.

In another embodiment, the common source lines 228 may be formed according to a damascene process. For example, a sacrificial layer pattern (not shown) may be formed on the second insulating interlayer 222. The sacrificial layer pattern may be formed to have a shape corresponding to that of the common source lines 228. A conductive layer (not shown) may then be formed on the second insulating interlayer 222 and the sacrificial layer pattern. The conductive layer may be planarized until an upper surface of the sacrificial layer pattern is exposed, thereby forming the common source lines 228 in the second insulating interlayer 222. The sacrificial layer pattern may be removed from the second insulating interlayer 222 after the common source lines 228 are formed.

According to the embodiments exemplarily described above, a plurality of common source lines 228 is formed over the semiconductor layer 216. That is, the plurality of common source lines 228 is formed on the second insulating interlayer 222. As a result, the number of insulating interlayers (and thickness of insulating material) required to be present between first gate structures 210 and the overlying semiconductor layer 216 may be reduced. Further, in embodiments where additional semiconductor layers 216 are formed (along with additional gate structures, impurity diffusion regions, and insulating interlayers), an extra insulating interlayer is not required because the common source lines 228 are formed on the topmost one of the additional insulating interlayers. Therefore, a manufacturing process of a NOR-type non-volatile memory device can be made relatively simple and the subsequently-formed second openings 230 may have a reduced aspect ratio.

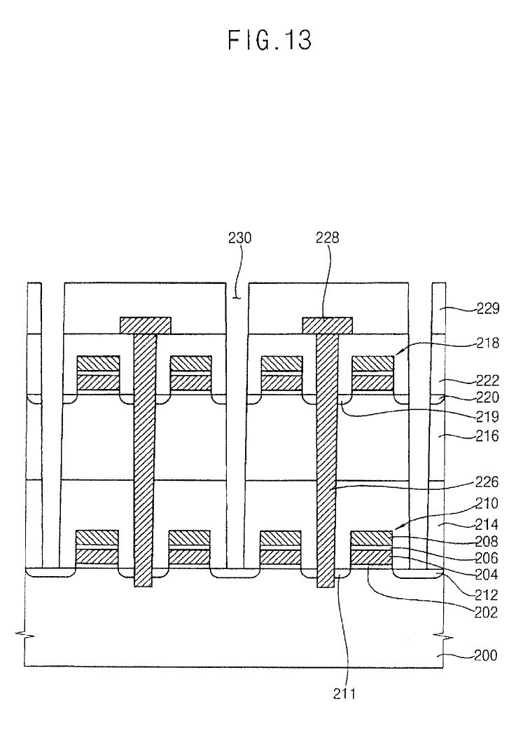

Referring to FIG. 13, a third insulating interlayer 229 is formed on the common source lines 228 and encloses of the common source lines 228. The third insulating interlayer 229 may, for example, include an oxide. The third insulating interlayer 229 may be formed using substantially the same process as that employed for forming the first insulating interlayer 214 described with reference to FIG. 6. Thus, any further explanation of the process for forming the third insulating interlayer 229 will be omitted.

Second openings 230 may be formed through the third insulating interlayer 229, the second insulating interlayer 222, the semiconductor layer 216 and the first insulating interlayer 214. In one embodiment, the second openings 230 may be formed by forming a sixth mask pattern (not shown) on the third insulating interlayer 229 and partially etching the third insulating interlayer 229, the second insulating interlayer 222, the semiconductor layer 216 and the first insulating interlayer 214 using the sixth mask pattern as an etching mask.

Upper portions of the lower drain regions 212 and side regions of the upper drain regions 220 may be exposed through the second openings 230.

According to one embodiment, a plurality of the common source lines 228 may be formed only over the semiconductor layer 216. Accordingly, common source lines 228 may not be formed within the semiconductor layer 216. As a result, the formation of an insulating interlayer for insulating the common source lines 228 from an overlying semiconductor layer may not be required. In addition, a distance between vertically stacked cells may decrease. Accordingly, an aspect ratio of the second opening may be made relatively low.

In one embodiment, spacers (not shown) may be formed on inner sidewalls of the second openings 230. The spacers may, for example, include a nitride material, or the like. For example, a nitride layer (not shown) may be formed along a profile of the second openings 230 so as to not fill the second openings 230. The nitride layer may then be partially removed by an anisotropic etch process to form the spacers on the inner sidewalls of the second openings 230.

The spacers formed on the inner sidewalls of the second openings 230 may help to prevent an electrical short between the conductive layer filling up the second openings 230 and the semiconductor layer 216. For example, when the semiconductor layer 216 has a relatively small thickness, the lower impurity diffusion regions 211 and 212 and the upper impurity diffusion regions 219 and 220 tend to be formed at an almost an entire surface of the semiconductor layer 216. Thus, spacers formed on the inner sidewalls of the second openings 230 may prevent an electrical short between the conductive layer filling up the second openings 230 and the semiconductor layer 216.

Referring back to FIG. 3, second contact plugs 232 are formed in the second openings 230. In one embodiment, the second contact plugs 232 may be formed by forming a fourth conductive layer (not shown) on the third insulating interlayer 229 to fill the second openings 230. The fourth conductive layer may, for example, include polysilicon doped with impurities. In one embodiment, the impurities may be substantially the same as those doped into the lower and upper impurity diffusion regions 211, 212, 219 and 220.

Bit lines 234 are then formed on the third insulating interlayer 229. In one embodiment, the bit lines 234 may be formed by forming a seventh mask pattern (not shown) on the fourth conductive layer and partially etching the fourth conductive layer using the seventh mask pattern as an etching mask. The bit lines 234 may extend along a direction that is perpendicular (or substantially perpendicular) to the common source lines 228.

The bit lines 234 are formed so as to contact the second contact plugs 232. Thus, the bit lines 234 may be electrically connected to the lower drain regions 212 and the upper drain regions 220.

Hereinafter, a NOR-type non-volatile memory device and a method of manufacturing a NOR-type non-volatile memory device in accordance with example embodiments of the present invention are described.

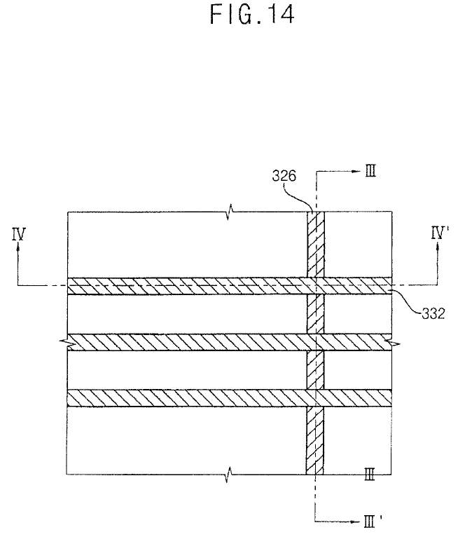

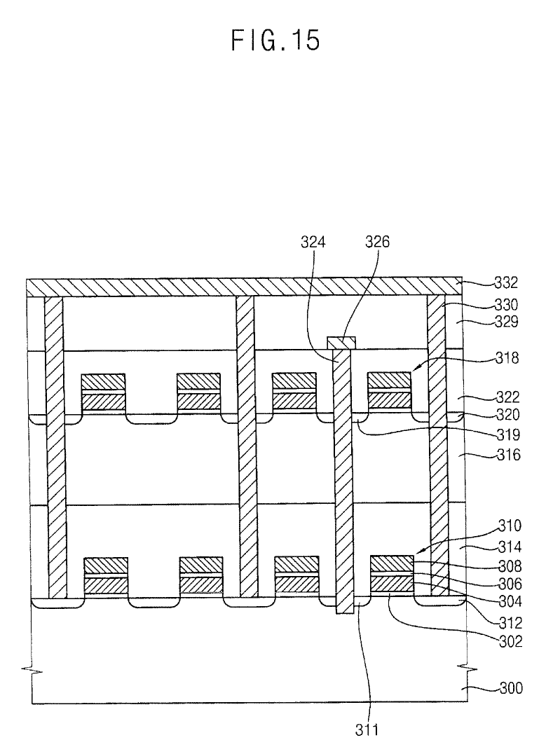

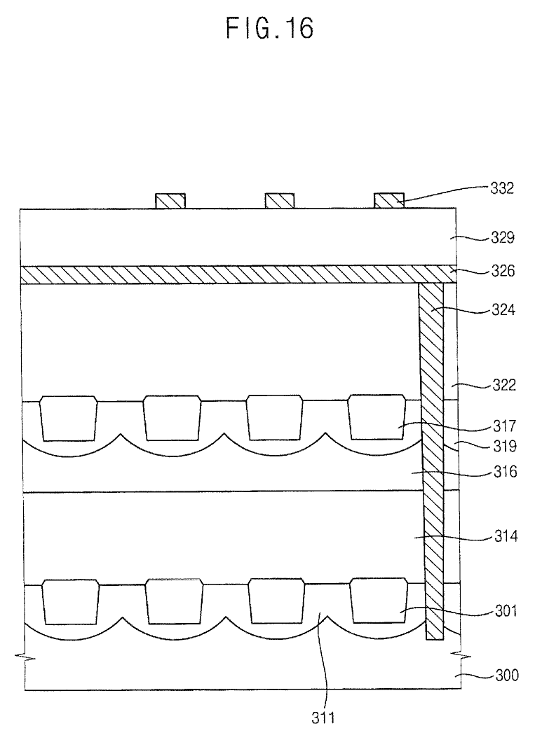

FIG. 14 is a cross-sectional view illustrating a NOR-type non-volatile memory device in accordance with exemplary embodiments. FIG. 15 is a cross-sectional view taken along line IV-IV′ shown in FIG. 14. FIG. 16 is a cross-sectional view taken along line III-III′ shown in FIG. 14.

Referring to FIGS. 14 to 16, a NOR-type non-volatile memory device includes a semiconductor substrate 300, a semiconductor layer 316, a plurality of gate structures 310 and 318, a plurality of impurity diffusion regions 311, 312, 319 and 320, a plurality of insulating interlayers 314, 322 and 329, a plurality of common source lines 326 and a plurality of bit lines 332. The gate structures 318 and the impurity diffusion regions 319 and 320 are formed on the semiconductor layer 316. The insulating interlayers 322 and 329 are formed on the semiconductor layer 316. The common source lines 326 are formed in insulating layer 329. The bit lines 332 are formed on insulating layer 329.

The semiconductor substrate 300 may, for example, include a silicon wafer (e.g., a single crystalline silicon wafer), or the like. As illustrated in FIG. 16, first isolation layer patterns 301 are formed at surfaces of the semiconductor substrate 300.

Lower impurity diffusion regions 311 and 312 are formed at surface portions of the semiconductor substrate 300. The lower impurity diffusion regions 311 and 312 enclose the first isolation layer patterns 301. The lower impurity diffusion regions 311 and 312 are connected to each other. The lower impurity diffusion regions 311 and 312 include lower source regions 311 (also referred to herein as “second impurity diffusion regions”) and lower drain regions 312 (also referred to herein as “third impurity diffusion regions”). The lower source regions 311 are connected to each other. The lower source regions 311 enclose the first isolation layer patterns 301.

A plurality of lower gate structures 310 (also referred to herein as “first gate structures”) are formed on the semiconductor substrate 300. The lower gate structures 310 are spaced apart from one another by a uniform distance. The lower gate structures 310 may extend along a first direction.

In one embodiment, each lower gate structure 310 may, for example, include a tunnel oxide layer pattern 302, a floating gate electrode 304, a dielectric layer pattern 306 and a control gate electrode 308. The floating gate electrode 304 may be formed under the dielectric layer pattern 306 and have an isolated hexahedral structure.

In one embodiment, the lower gate structures 310 may include first spacers (not shown) formed on sidewalls thereof.

A first insulating interlayer 314 is formed on the semiconductor substrate 300 on which the lower gate structures 310 and the lower impurity diffusion regions 311 and 312 are formed. The first insulating interlayer 314 may include, for example, an oxide (e.g., silicon oxide), or the like.

In one embodiment, connecting members (not shown) may be further formed through the first insulating interlayer 314. Each of the connecting members may connect an upper surface of the semiconductor substrate 300 to a lower surface of the semiconductor layer 316. The connecting members may be formed using a selective epitaxial growth process by using the semiconductor substrate 300 as a seed. An exemplary process for forming the connecting members is described in greater detail with respect to FIGS. 22 and 23.

The semiconductor layer 316 is formed on the first insulating interlayer 314. Second isolation layer patterns 317 and upper impurity diffusion regions 319 and 320 are formed at surface portions of the semiconductor layer 316. Upper gate structures 318 (also referred to herein as “second gate structures”) are formed on the semiconductor layer 316. The upper gate structures 318 and the upper impurity diffusion regions 319 and 320 have substantially the same structures as those of the lower gate structures 310 and the lower impurity diffusion regions 311 and 312. Accordingly, the upper impurity diffusion region 319 may be referred to as an upper source region 319 (or a “second impurity diffusion region”) and the upper impurity diffusion region 320 may be referred to as an upper drain region 320 (or a “fourth impurity diffusion region”). Thus, any further explanation of the structures of the upper gate structures 318 and the upper impurity diffusion regions 319 and 320 will be omitted to avoid a redundancy.

A second insulating interlayer 322 is formed on the semiconductor layer 316. The common source line 326 is formed on the second insulation interlayer 322. The common source line 326 extends in parallel with the lower and the upper gate structures 310 and 318. The common source line 326 is formed such that a location of the common source line 326 relative to the semiconductor substrate 300 substantially corresponds to a location of one of the lower and the upper gate structures 310 and 318.

A first contact plug 324 electrically connects the common source line 326 to the lower and the upper source regions 311 and 319. For example, the first contact plug 324 is formed through the second insulating interlayer 322, the semiconductor layer 316 and the first insulating interlayer 314. The first contact plug 324 may extend into the semiconductor substrate 300.

A lower portion of the first contact plug 324 may contact the lower source region 311 and a side portion of the first contact plug 324 may contact the upper source region 319. Thus, the first contact plug 324 may electrically connect the common source line 326 to the lower and the upper source regions 311 and 319.

A third insulating interlayer 328, a plurality of second contact plugs 330 and a plurality of bit lines 332 may have substantially the same structures and compositions as those of the third insulating interlayer 229, second contact plugs 232 and bit lines 234 as illustrated with reference to FIGS. 2 to 4. Thus, any further explanation of the third insulating interlayer 328, the second contact plugs 330 and the bit lines 332 will be omitted.

Hereinafter, an exemplary method of manufacturing the NOR-type non-volatile memory device in FIGS. 14 to 16 will now be described.

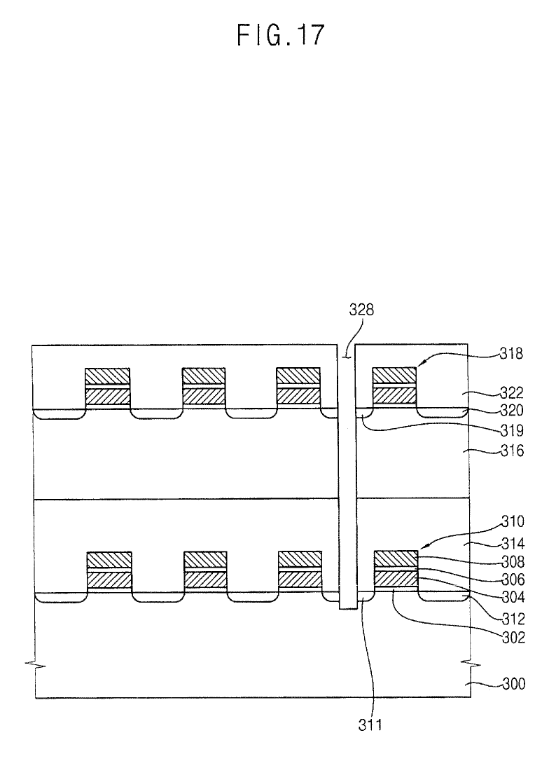

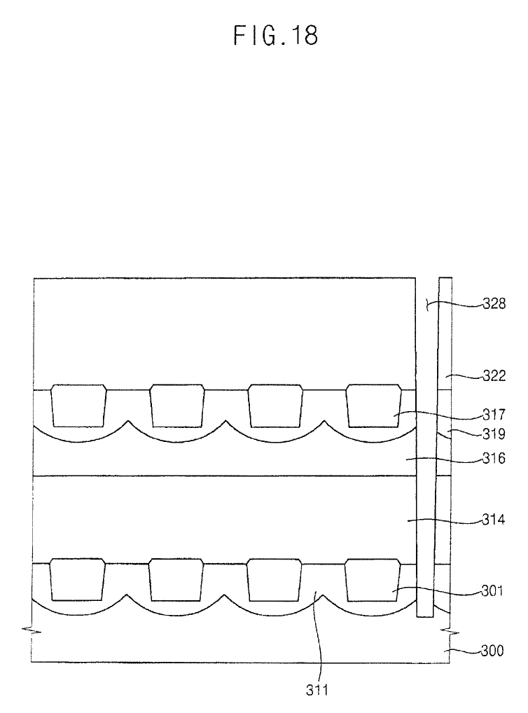

FIGS. 17 and 18 are cross-sectional views illustrating a method of manufacturing the NOR-type non-volatile memory device in accordance with exemplary embodiments of the present invention. Specifically, FIG. 17 is a cross-sectional view taken along line IV-IV′ shown in FIG. 14 and FIG. 18 is a cross-sectional view taken along line III-III′ shown in FIG. 14.

Referring to FIGS. 16 and 17, first isolation layer patterns 301 are formed at surface portions of a semiconductor substrate 300 (e.g., a silicon wafer). The first isolation layer patterns 301 may be formed using an isolation process such as a shallow trench isolation process to define first active regions.

Lower source regions 311 are formed at the surface portions of the semiconductor substrate 300 and are further formed so as to enclose the first isolation layer patterns 301. In one embodiment the lower source regions 311 may be formed by removing an oxide material within the first isolation layer patterns 301 to form trenches (not shown) in the semiconductor substrate 300. Impurities are then implanted into bottom surface portions of the trenches and surfaces of the first active regions at a relatively high concentration. Further, impurities are implanted into side surface portions of the trenches at a relatively low concentration to form the lower source regions 311. An oxide layer may then be formed to fill the trench so that the first isolation layer patterns 301 are re-formed at the surface portions of the semiconductor substrate 300.

Lower gate structures 310 are formed on the semiconductor substrate 300. Subsequently, impurities are implanted through a surface of the semiconductor substrate 300 exposed between adjacent lower gate structures 310 using the lower gate structures 310 as an ion implantation mask to form lower drain regions 312 at the surface portions of the semiconductor substrate 300. Accordingly, the lower impurity diffusion regions 311 and 312 including the lower source regions 311 and the lower drain regions 312 are formed at the surface portions of the semiconductor substrate 300. The lower source regions 311 are electrically connected to one another. The lower source regions 311 enclose the first isolation layer patterns 301.

A first insulating interlayer 314 is formed on the semiconductor substrate 300 to fill gaps between adjacent ones of the lower gate structures 310. A semiconductor layer 316 is then formed on the first insulating interlayer 314.

In one embodiment, processes for forming the lower gate structures 310, the first insulating interlayer 314 and the semiconductor layer 316 may be substantially the same as those for forming the lower gate structures 210, the first insulating interlayer 214 and the semiconductor layer 216 that are described with reference to FIGS. 6 and 7. Thus, any further explanation of the processes for forming the lower gate structures 310, the first insulating interlayer 314 and the semiconductor layer 316 will be omitted.

In one embodiment, second isolation layer patterns 317 and upper impurity diffusion regions 319 and 320 may be formed by substantially the same processes as those for forming the first isolation layer pattern 301 and the lower impurity diffusion regions 311 and 312. Further, upper gate structures 318 and second insulating interlayer 322 may be formed on the semiconductor layer 316.

Referring to FIG. 18, a first opening 328 is formed through the second insulating interlayer 322, the semiconductor layer 316 and the first insulating interlayer 314. In one embodiment, the first opening 328 may be formed by forming a second mask pattern (not shown) on the second insulating interlayer 322 and then partially etching the second insulating interlayer 322, the semiconductor layer 316 and the first insulating interlayer 314 using the second mask pattern as an etching mask.

In one embodiment, the first opening 328 may extend into the semiconductor substrate 300. The first opening 328 is formed adjacent to one of the lower and the upper gate structures 310 and 318. The first opening 328 exposes one of the lower source regions 311 electrically connected to one another. In one embodiment, the first opening 328 may expose a sidewall of one of the upper source regions 319.

Referring back to FIG. 16, a first contact plug 324 is formed in the first opening 328. In one embodiment, the first contact plug 324 may be formed by forming a first conductive layer (not shown) on the second insulating interlayer 322 to fill the first opening 328. The first contact plug 324 contacts a cross section of one of the lower source regions 311 connected to each other and one of the upper source regions 320.

The first conductive layer is then patterned to form a common source line 326 on the second insulating interlayer 322. The common source line 326 is formed to extend along a direction parallel (or substantially parallel) with the first and the second isolation layer patterns 301 and 317. Further, the common source line 326 is electrically connected to the first contact plug 324. Thus, the common source line 326 is electrically connected to the lower and the upper source regions 311 and 319.

According to the embodiments exemplarily described above, the common source line 326 is formed over the semiconductor layer 316. That is, the common source line 326 is formed on the second insulating interlayer 322. Thus, the common source line 326 does not contact the semiconductor layer 316. As a result, the number of insulating interlayers (and thickness of insulating material) required to be present between the first gate structures 310 and the overlying semiconductor layer 316 may be reduced. Further, in embodiments where additional semiconductor layers 316 are formed (along with additional gate structures, impurity diffusion regions, and insulating interlayers), an extra insulating interlayer is not required because the common source line 326 is formed on the topmost one of the additional insulating interlayers. Therefore, a manufacturing process of a NOR-type non-volatile memory device can be made relatively simple and the subsequently-formed second openings (not shown) may have a reduced aspect ratio. Further, the common source line 326 may be formed to contact only one of the source regions electrically connected to one another so that a cell area may decrease.

Referring back to FIG. 15, a third insulating interlayer 329 is formed on the second insulating interlayer 322 to cover the common source line 326. Second openings (not shown) may be formed through the third insulating interlayer 329, the second insulating interlayer 322, the semiconductor layer 316 and the first insulating interlayer 314. In one embodiment, the second openings may be formed by forming a third mask pattern (not shown) on the third insulating interlayer 329 and partially etching the third insulating interlayer 329, the second insulating interlayer 322, the semiconductor layer 316 and the first insulating interlayer 314 using the third mask pattern as an etching mask. The second openings may expose upper surfaces of the lower drain regions 312 and cross sections of the upper drain regions 320.

In one embodiment, the second openings may extend into the semiconductor substrate 300.

Second contact plugs 330 and bit lines 332 are formed by substantially the same processes as those for forming the second contact plugs 232 and the bit lines 234 that are described with reference to FIGS. 13 and 14. The second contact plugs 330 contact the bit lines 332, upper surfaces of the lower drain regions 312 and cross sections of the upper drain regions 320. Accordingly, the bit lines 332 are electrically connected to the lower drain regions 312 and the upper drain regions 320.

Hereinafter, processes for forming semiconductor layers 216 and 316 on the first insulating interlayer 214 and 314 formed on the semiconductor substrate 200 and 300 will be described in greater detail. Generally, the processes for forming the semiconductor layers on the first insulating interlayer may include a bonding process and a selective epitaxial growth process.

An exemplary bonding process for forming a semiconductor layer on the first insulating interlayer will be described.

FIGS. 19 to 21 are cross-sectional views illustrating an exemplary process forming a semiconductor layer on a first insulating interlayer using a die bonding process.

Referring to FIG. 19, a bulk silicon substrate 400 serving as a semiconductor layer is provided.

Hydrogen ions are implanted into the bulk silicon substrate 400 using an ion implantation process to form a hydrogen implanted layer 402 at a surface region of the bulk silicon substrate 400. The hydrogen implanted layer 402 has a thickness corresponding to that of the semiconductor layer. The thickness of the hydrogen implanted layer 402 may be adjusted by controlling an energy applied in the ion implantation process.

Referring to FIG. 20, the bulk silicon substrate 400 including the hydrogen implanted layer 402 is bonded to the first insulating interlayer 214. An upper surface of the hydrogen implanted layer 402 contacts an upper surface of, for example, the first insulating interlayer 214. As described previously with respect to FIGS. 3 and 15, the first insulating interlayer 214 is formed on the semiconductor substrate 200 including the lower gate structures 210 and the lower impurity diffusion regions 211 and 212. The first insulating interlayer 214 electrically isolates the semiconductor layer 402 from the semiconductor substrate 200. In one embodiment, the hydrogen implanted layer 402 is reversibly bonded to the first insulating interlayer 214 by a Van der Waal's force where various molecules are weakly aggregated to one another.

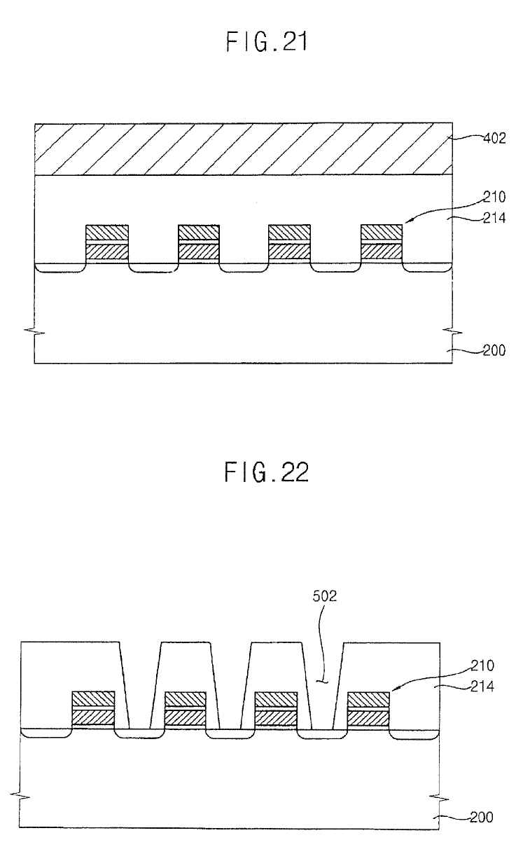

Referring to FIG. 21, a first thermal treatment process and a second thermal treatment process are performed on the resultant structure in which the hydrogen implanted layer 402 is bonded to the first insulating interlayer 214.

The first thermal treatment process may be performed at a temperature of about 400° C. to about 600° C. to weaken the bond between the bulk silicon substrate 400 and the hydrogen implanted layer 402. The second thermal treatment process may be carried out at a temperature over about 1,000° C. to separate (i.e., remove) the bulk silicon substrate 400 from the hydrogen implanted layer 402. As a result, the first insulating interlayer 214 and the hydrogen implanted layer 402 are irreversibly boned to each other. Therefore, the semiconductor layer 402 is formed on the first insulating interlayer 214.

Although not shown in FIG. 21, an upper surface of the semiconductor layer 402 may be planarized using a planarization process.

An exemplary selective epitaxial growth process for forming a semiconductor layer on the first insulating interlayer will now be described.

FIGS. 22 to 24 are cross-sectional views illustrating process for forming a semiconductor layer on a semiconductor substrate including a first insulating interlayer by using a selective epitaxial growth process.

Referring to FIG. 22, a semiconductor substrate 200 on which the first insulating interlayer 214 is formed, is exemplarily provided. The semiconductor substrate 200 may, for example, include a single crystalline silicon substrate. Lower gate structures and the lower impurity diffusion regions are formed on the semiconductor substrate 200 as illustrated in FIGS. 3 and 15.

Openings 502 are formed in the first insulating interlayer 214. In one embodiment, the openings 502 may be formed by forming a mask pattern (not shown) on the first insulating interlayer 214 and partially etching the first insulating interlayer 214 using the mask pattern as an etching mask. The openings 502 are formed through the first insulating interlayer 214 so that an upper surface of the semiconductor substrate 200 may be partially exposed.

Referring to FIG. 23, a selective epitaxial growth process is performed using a portion of the semiconductor substrate 200 exposed through the openings 502 as a seed layer to form a connecting member 504 filling the openings 502. The connecting member 504 may have a crystalline structure. The connecting member 504 and the semiconductor substrate 200 may include substantially the same material.

Subsequently, a first single crystalline silicon layer (not shown) may be formed on the first insulating interlayer 214 using the connecting member 504 as a seed. The upper surface of the first single crystalline silicon layer may be planarized (e.g., polished).

Next, an amorphous silicon layer (not shown) is formed on the first single crystalline silicon layer. The amorphous silicon layer is then crystallized to transform the amorphous silicon layer into a second single crystalline silicon layer. The amorphous silicon layer may be crystallized by a solid phase crystallization process, a laser crystallization process, or the like or a combination thereof. The amorphous silicon layer is crystallized using the first single crystalline silicon layer as a seed layer such that the second single crystalline silicon layer may have a crystalline structure that is substantially the same as the crystalline structure of the first single crystalline silicon layer. Accordingly, the first single crystalline silicon layer and the second single crystalline silicon layer may be formed on the first insulating interlayer 214 including the connecting member 504.

In one embodiment, a laser epitaxial growth process may be further performed on the first single crystalline silicon layer and the second single crystalline silicon layer to improve crystalline structures of the first single crystalline silicon layer and the second single crystalline silicon layer.

Further, an epitaxial growth process may be carried out using the second single crystalline silicon layer as a seed layer to form a third silicon crystalline silicon layer on the second single crystalline silicon layer so that a thickness of the semiconductor layer 506 may be adjusted.

Upon forming the first single crystalline silicon layer, the second single crystalline silicon layer and the third single crystalline silicon layer, the semiconductor layer 506 shown in FIG. 24 may be formed on the first insulating interlayer 214. In this embodiment, the semiconductor layer 506 can be characterized as including a plurality of semiconductor sub-layers that include the first, second and third single crystalline silicon layers. It will be appreciated that the semiconductor layer 506 may include less than three semiconductor sub-layers or more than three semiconductor sub-layers. It will also be appreciated that the semiconductor layer 316 may be formed using any of the above-described bonding and selective epitaxial growth processes. Moreover, the thickness of the semiconductor layers 216 and 316 may be controlled by varying the parameters of the two processes described above.

An exemplary method of erasing a data from a NOR-type non-volatile memory device in accordance with a thickness of a semiconductor layer will now be described.

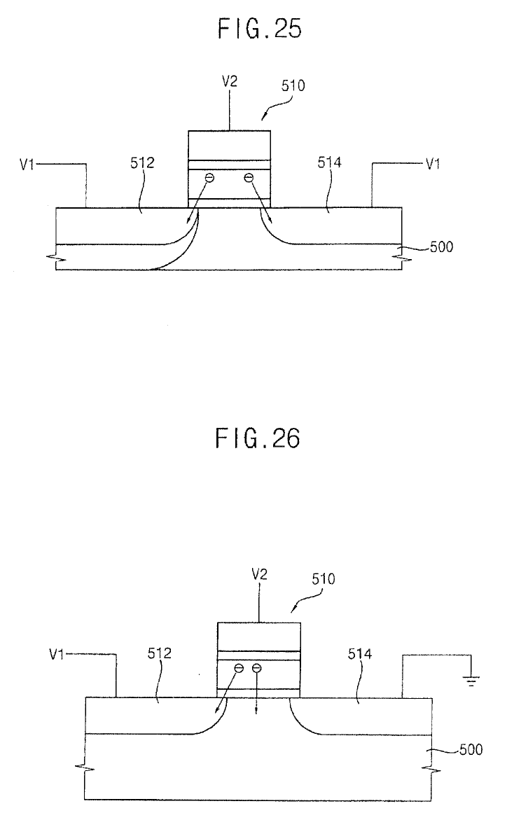

FIG. 25 is a cross-sectional view illustrating a mechanism of erasing a data from a NOR-type non-volatile memory device including a semiconductor layer having the substantially the same thickness as that of an impurity diffusion region formed in the semiconductor layer.

Referring to FIG. 25, a semiconductor layer 500 has substantially the same thickness as that of an impurity diffusion region. A first voltage is applied to a common source line and a bit line. A second voltage substantially lower than the first voltage is applied to a gate structure 510. Thus, a floating state of the semiconductor layer 500 may be maintained.

When the first voltage is applied to the common source line and the bit line and the second voltage is applied to the gate structure 510, a floating gate electrode discharges electrons through a source region 512 electrically connected to the common source line and a drain region 514 electrically connected to the bit line. Thus, data may be erased from a NOR-type non-volatile memory device.

For example, when a second voltage of about −9V is applied to the gate structure 510 and a first voltage of about 7V is applied to the bit line and the common source line, the floating state of the semiconductor layer 500 may be maintained. Further, electrons stored in the floating gate electrode migrate along a side face of the drain region 514 and a side face of the source region 512 by an F-N tunneling. Thus, data may be erased from the NOR-type non-volatile memory device.

FIG. 26 is a cross-sectional view illustrating a mechanism of erasing data from a NOR-type non-volatile memory device including a semiconductor layer having a thickness greater than that of an impurity diffusion region formed in the semiconductor layer.

A semiconductor layer 500 has a thickness greater than that of an impurity diffusion region formed in the semiconductor layer. A first voltage is applied to a common source line and the semiconductor layer 500. A second voltage lower than the first voltage is applied to a gate structure 510. Thus, a floating state of the bit line is maintained.

When the first voltage is applied to the common source line and the semiconductor layer 500 and the second voltage is applied to the gate structure 510, a floating gate electrode discharges electrons through a source region 512 electrically connected to the common source line and the semiconductor layer 500. Thus, data may be erased from a NOR-type non-volatile memory device.

For example, when a second voltage of about −9V is applied to the gate structure 510 and a first voltage of about 7V is applied to the common source line and the semiconductor layer 500, a floating state of the semiconductor layer 500 may be maintained. Further, electrons stored in the floating gate electrode migrate along a side face of the source region 512 and the semiconductor layer 500 by an F-N tunneling. Thus, data may be erased from the NOR-type non-volatile memory device.

According to exemplary embodiments, a plurality of common source lines are formed only on top of a semiconductor layer. Accordingly, in embodiments where the semiconductor layer includes a plurality of semiconductor sub-layers, the common source lines may not be formed on each semiconductor sub-layer. Thus, a manufacturing process of a NOR-type non-volatile memory device may be simplified. In addition, an aspect ratio of a second contact plug electrically connected to a bit line may decrease.

Further, when a NOR-type non-volatile memory device has source regions connected to one another, only one common source line need be formed adjacent to one of gate structures. Thus, an overall cell area may decrease. What follows is non-limiting description of some embodiments exemplarily described above.

In one embodiment, a memory device includes a semiconductor substrate, a first insulating interlayer, a semiconductor layer, a second insulating interlayer, at least one contact plug, at least one common source line, a semiconductor substrate, a first insulating interlayer, a semiconductor layer, a second insulating interlayer, at least one contact plug and at least one common source line. The semiconductor substrate includes lower gate structures and lower impurity diffusion regions. The first insulating interlayer is formed on the semiconductor substrate. The semiconductor layer is formed on the first insulating interlayer. The semiconductor layer includes upper gate structures and upper impurity diffusion regions. The second insulating interlayer is formed on the semiconductor layer. The contact plug electrically connects the lower impurity diffusion regions to the upper impurity diffusion regions. The common source line is formed on the second insulating interlayer. The common source line is electrically connected to the contact plug.

The memory device may further include a connecting member formed through the first insulating interlayer to have a column shape. The connecting member may combine the semiconductor substrate to the semiconductor layer. The connecting member may include substantially the same material as that included in the semiconductor substrate. The lower impurity diffusion regions may be electrically isolated from the upper impurity diffusion regions. A plurality of contact plugs may make contact with the lower impurity diffusion regions and the upper impurity diffusion regions. The lower impurity diffusion regions may be connected to one another. The upper impurity diffusion regions may be connected to one another. The contact plug may electrically connect one of the lower impurity diffusion regions to one of the upper impurity diffusion regions. The memory device may further include third impurity diffusion regions formed at portions of the semiconductor substrate between the lower gate structures and fourth impurity diffusion regions formed at surface portions of the semiconductor layer between the upper gate structures. The memory device may further include a third insulating interlayer, second contact plugs and bit lines. The third insulating interlayer may be located on the common source line and the second insulating interlayer. The second contact plugs may electrically connect the third impurity diffusion regions to the fourth impurity diffusion regions. The bit lines may be formed on the third insulating interlayer. The bit lines may be electrically connected to the second contact plugs. The second contact plugs may include polysilicon doped with impurities. The impurities may be substantially the same impurities as those included in the first to fourth impurity diffusion regions. The memory device may further include spacers formed on sidewalls of the contact plug, the spacers including nitride.

In some embodiments, there is provided a method of manufacturing a memory device. In the method, lower gate structures and lower impurity diffusion regions are formed on a semiconductor substrate. A first insulating interlayer is formed on the semiconductor substrate. A semiconductor layer is formed on the first insulating interlayer. The semiconductor layer includes upper gate structures and upper impurity diffusion regions. A second insulating interlayer is formed on the semiconductor layer. At least one contact plug electrically connecting the lower impurity diffusion regions to the upper impurity diffusion regions is formed. At least one common source line is formed on the second insulating interlayer. The common source line is electrically connected to the contact plug.

The lower impurity diffusion regions may be electrically isolated from the upper impurity diffusion regions. To form the lower impurity diffusion regions and the upper impurity diffusion regions, impurities are implanted into a surface portion of the semiconductor substrate exposed between the lower gate structures and a surface portion of the semiconductor layer exposed between the upper gate structures. The lower impurity diffusion regions may be connected to the upper impurity diffusion regions. To form the lower impurity diffusion regions and the upper impurity diffusion regions, trenches are formed in the semiconductor substrate and the semiconductor layer. Impurities are diffused into bottom surface portions of the trenches and at surface portions of active regions defined by the trenches at a first concentration. Impurities are diffused at side surface portion of the trenches at a second concentration substantially lower than the first concentration. To form the semiconductor layer, openings are formed through the first insulating interlayer such that an upper face of the semiconductor substrate is exposed. Connecting members filling up the openings to connect the semiconductor substrate to the semiconductor layer and a single crystalline silicon layer are formed on the first insulating interlayer by performing a selective epitaxial growth process on the exposed semiconductor substrate. To manufacture the memory device, an amorphous silicon layer may be formed on the single crystalline silicon layer. The amorphous silicon layer is crystallized to transform the amorphous silicon layer to a second single crystalline silicon layer. The amorphous silicon layer is crystallized by performing a solid phase crystallization process or a laser crystallization process. To form the semiconductor layer, a bulk silicon substrate is provided. Hydrogen is implanted into a surface portion of the bulk silicon substrate to form a hydrogen implanted layer. The hydrogen implanted layer is bonded to the bulk silicon substrate. The bulk silicon substrate is removed from the hydrogen implanted layer. To manufacture the memory device, third impurity diffusion regions are formed at a surface portion of the semiconductor substrate. Fourth impurity diffusion regions are formed at surface portions of the semiconductor layer. To manufacture the memory device, third insulating interlayer may be formed on the common source line and the second insulating interlayer. Second contact plugs electrically connecting the third impurity diffusion regions to the fourth impurity diffusion regions may be formed. Bit lines may be formed on the third insulating interlayer. The bit lines may be electrically connected to the second contact plugs. To form the second contact plugs, openings are formed through the third insulating interlayer, the second insulating interlayer, the semiconductor layer and the first insulating interlayer. Spacers are formed on sidewalls of the openings, the spacer including nitride. A conductive layer may be formed on the third insulating interlayer to fill the openings. The conductive layer may be formed using polysilicon doped with impurities. The impurities may be substantially the same as those of the first to fourth impurity diffusion regions.

According to some embodiments, a common source lines is formed only on a top semiconductor layer of multiple semiconductor layers. That is, the common source line may not be formed on each of the semiconductor layers. Thus, a manufacturing process of a memory device may become simple. In addition, an aspect ratio of a second contact plug electrically connected to a bit line may decrease. An aspect ratio of a second contact plug electrically connected to a bit line may also decrease. Further, when a memory device has impurity diffusion regions connected to one another, only one common source line may be formed adjacent to one of gate structures. Thus, an overall cell area may decease. In addition, a high integration degree of the memory device may be achieved.

The foregoing is illustrative of the present invention and is not to be construed as limiting thereof. Although a few example embodiments have been described, those skilled in the art will readily appreciate that many modifications are possible in the example embodiments without materially departing from the novel teachings and advantages of this invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A memory device comprising:
a semiconductor substrate including first gate structures and first impurity diffusion regions;
a first insulating interlayer formed on the semiconductor substrate;
a semiconductor layer formed on the first insulating interlayer, the semiconductor layer including second gate structures and second impurity diffusion regions;
a second insulating interlayer formed on the semiconductor layer;
a contact plug electrically connecting one of the first impurity diffusion regions to one of the second impurity diffusion regions; and
a common source line formed on the second insulating interlayer, the common source line electrically connected to the contact plug.

2. The memory device of claim 1, further comprising a connecting member formed through the first insulating interlayer and connecting the semiconductor substrate to the semiconductor layer.

3. The memory device of claim 2, wherein the connecting member and the semiconductor substrate include substantially the same material.

4. The memory device of claim 1, wherein the first impurity diffusion regions are electrically isolated from the second impurity diffusion regions, the memory device further comprising:
a plurality of contact plugs, wherein each of the plurality of contact plugs electrically connects one of the first impurity diffusion regions to a corresponding one of the second impurity diffusion regions.

5. The memory device of claim 1, wherein the first impurity diffusion regions are connected to one another.

6. The memory device of claim 5, wherein the second impurity diffusion regions are connected to one another.

7. The memory device of claim 1, wherein the contact plug is formed through the first insulating interlayer, the semiconductor layer and the second insulating interlayer.

8. The memory device of claim 1, further comprising:
third impurity diffusion regions formed at surface portions of the semiconductor substrate between the first gate structures; and
fourth impurity diffusion regions formed at surface portions of the semiconductor layer between the second gate structures.

9. The memory device of claim 8, further comprising:
a third insulating interlayer overlying the common source line and the second insulating interlayer;
second contact plugs electrically connecting the third impurity diffusion regions to corresponding ones of the fourth impurity diffusion regions; and
bit lines formed on the third insulating interlayer and electrically connected to the second contact plugs.

10. The memory device of claim 9, wherein at least one of the second contact plugs includes polysilicon doped with impurities.

11. The memory device of claim 10, wherein the impurities included in the at least one second contact plug are substantially the same as impurities included in the first to fourth impurity diffusion regions.

12. The memory device of claim 10, further comprising spacers located on sidewalls of the second contact plugs, the spacers including a nitride material.

13. A method of manufacturing a memory device, the method comprising:
forming first gate structures and first impurity diffusion regions on a semiconductor substrate;
forming a first insulating interlayer on the semiconductor substrate;
forming a semiconductor layer on the first insulating interlayer, the semiconductor layer including second gate structures and second impurity diffusion regions;
forming a second insulating interlayer on the semiconductor layer;
forming a contact plug electrically connecting one of the first impurity diffusion regions to one of the second impurity diffusion regions; and
forming a common source line on the second insulating interlayer, the common source line being electrically connected to the contact plug.

14. The method of claim 13, wherein the first impurity diffusion regions are electrically isolated from the second impurity diffusion regions,
wherein forming the first impurity diffusion regions comprises implanting impurities into a surface portion of the semiconductor substrate exposed between the first gate structures, and
wherein forming the second impurity diffusion regions comprises implanting impurities into a surface portion of the semiconductor layer exposed between the second gate structures.

15. The method of claim 13, wherein each of the first impurity diffusion regions are electrically connected to each of the second impurity diffusion regions,
wherein forming the first impurity diffusion regions comprises:
forming first trenches in the semiconductor substrate, the first trenches defining first active regions in the semiconductor substrate;
implanting impurities into bottom surface portions of the first trenches and surface portions of the first active regions at a first concentration; and
implanting impurities into side surface portions of the first trenches at a second concentration lower than the first concentration, and
wherein forming the second impurity diffusion regions comprises:
forming second trenches in the semiconductor layer, the second trenches defining second active regions in the semiconductor layer;
implanting impurities into bottom surface portions of the second trenches and surface portions of second active regions at the first concentration; and
implanting impurities into side surface portions of the second trenches at the second concentration.

16. The method of claim 13, wherein forming the semiconductor layer comprises:
forming an opening through the first insulating interlayer to expose an upper surface of the semiconductor substrate;
performing a selective epitaxial growth process on the exposed upper surface of the semiconductor substrate to form a connecting member filling the opening; and
performing a selective epitaxial growth process on the connecting member to form a first single crystalline silicon layer on the first insulating interlayer.

17. The method of claim 16, further comprising:
forming an amorphous silicon layer on the first single crystalline silicon layer; and
crystallizing the amorphous silicon layer to transform the amorphous silicon layer to a second single crystalline silicon layer.

18. The method of claim 17, wherein crystallizing the amorphous silicon layer comprises performing at least one of a solid phase crystallization process and a laser crystallization process.

19. The method of claim 13, wherein forming the semiconductor layer comprises:
providing a bulk silicon substrate;
implanting hydrogen through a surface of the bulk silicon substrate to form a hydrogen implanted layer;
bonding the hydrogen implanted layer to the first insulating interlayer; and
removing the bulk silicon substrate from the hydrogen implanted layer.

20. The method of claim 13, further comprising:
forming third impurity diffusion regions at surface portions of the semiconductor substrate; and
forming fourth impurity diffusion regions at surface portions of the semiconductor layer.

21. The method of claim 20, further comprising:
forming a third insulating interlayer on the common source line and the second insulating interlayer;
forming second contact plugs electrically connecting the third impurity diffusion regions to corresponding ones of the fourth impurity diffusion regions; and
forming bit lines on the third insulating interlayer, the bit lines being electrically connected to the second contact plugs.

22. The method of claim 21, wherein forming the second contact plugs comprises:
forming openings through the third insulating interlayer, the second insulating interlayer, the semiconductor layer and the first insulating interlayer;
forming spacers on sidewalls of the openings, the spacers including a nitride material; and
forming a conductive layer on the third insulating interlayer to fill the openings.

23. The method of claim 22, wherein the conductive layer includes polysilicon doped with impurities.

24. The method of claim 23, wherein the impurities included in the conductive layer are substantially the same as impurities included in the first to fourth impurity diffusion regions.
